(19) United States
(12) Patent Application Publication
(10) Pub. No.: US 2020/0108584 A1
(43) Pub. Date: Apr. 9, 2020

(54) GRAPHENE-BASED LAMINATE, METHOD OF PREPARING THE SAME, AND TRANSPARENT ELECTRODE AND ELECTRONIC DEVICE EACH INCLUDING THE GRAPHENE-BASED LAMINATE

(71) Applicant: HANWHA AEROSPACE CO.,LTD, Changwon-si (KR)

(72) Inventors: Sunae SEO, Seoul (KR); Somyeong SHIN, Seoul (KR); Jin Sung PARK, Changwon-si (KR); Jong Hyuk YOON, Changwon-si (KR); Jin Ho JANG, Changwon-si (KR); Seung Jin CHAE, Changwon-si (KR)

(73) Assignee: HANWHA AEROSPACE CO.,LTD, Changwon-si (KR)

(21) Appl. No.: 16/264,167

(22) Filed: Jan. 31, 2019

(30) Foreign Application Priority Data
Oct. 4, 2018 (KR) 10-2018-0118493
Nov. 7, 2018 (KR) 10-2018-0136169

(51) Int. Cl. B32B 9/04; H01L 29/786; H01L 29/267; H01L 51/52; B32B 27/36

(52) U.S. Cl. CPC B32B 9/045; H01L 29/7869; H01L 29/1606; H01L 51/5206; B32B 27/36; H01L 29/267

(57) ABSTRACT

Provided are a graphene-based laminate, a method of preparing the same, and a transparent electrode and an electronic device each including the graphene-based laminate. The graphene-based laminate includes a substrate, a graphene layer including graphene and disposed on at least one surface of the substrate, and a metal oxide layer disposed on at least one surface of the graphene layer, wherein the metal oxide layer includes a metal oxide having a greater work function than that of the graphene, and the metal oxide layer includes the metal oxide in an amount of 1 μg to 1 mg per unit area of 1 cm² of the graphene layer.

### CROSS-REFERENCE TO THE RELATED APPLICATION

This application claims priority from Korean Patent Application No. 10-2018-0118493, filed on Oct. 4, 2018, and No. 10-2018-0136169, filed on Nov. 7, 2018, in the Korean Intellectual Property Office, the disclosures of which are incorporated herein in their entireties by reference.

### BACKGROUND

### 1. Field

One or more exemplary embodiments of the inventive concept relate to a graphene-based laminate, a method of preparing the same, and a transparent electrode and an electronic device each including the graphene-based laminate.

### 2. Description of the Related Art

Graphene is a two-dimensional substance formed of carbon atoms arranged in a hexagonal lattice and 1.42 Å apart. Due to excellent properties in terms of strength, thermal conductivity, and electron mobility, graphene may be applied to displays, secondary batteries, solar cells, light-emitting devices, sensors, or various types of graphene-based electronic device.

Graphene is generally produced by mechanical exfoliation, chemical deposition, epitaxial growth, or chemical exfoliation. Since graphene produced in these ways has a sheet resistance value of thousands of Ω/sq, various attempts have been made to reduce the sheet resistance value to apply graphene to industrial fields.

As one of these attempts, a method of stacking graphene in multiple layers has been introduced. However, with this method, the number of processes, costs, and the rate of defects when repeated may increase, and thus researches are in progress to increase electron mobility or charge density in a single layer. However, these researches also have limitations in considerably lowering sheet resistance.

Therefore, there is still a need to develop graphene structures capable of reducing sheet resistance values and efficiently increasing sheet resistance reduction rates and methods of preparing the same.

### SUMMARY

Various embodiments provide a graphene-based laminate, a method of preparing the graphene-based laminate, a transparent electrode including the graphene-based laminate, and an electronic device including the transparent electrode.

Additional aspects will be set forth in part in the description which follows and, in part, will be apparent from the description, or may be learned by practice of the presented embodiments.

According to one or more embodiments, there is provided a graphene-based laminate which may include: a substrate; a graphene layer formed of graphene and disposed on at least one surface of the substrate; and a metal oxide layer disposed on at least one surface of the graphene layer, wherein the metal oxide layer includes a metal oxide having a greater work function than that of the graphene, and the metal oxide layer includes the metal oxide in an amount of 1 μg to 1 mg per unit area of 1 cm² of the graphene layer.

According to one or more embodiments, there is provided a method of preparing a graphene-based laminate. The method may include: preparing a metal oxide solution by adding a metal oxide to a mixture of an alcohol solvent and an oxidant and stirring the mixture; and coating the metal oxide solution on at least one surface of a graphene layer formed of graphene to form a metal oxide layer thereon, thereby obtaining the graphene-based laminate.

According to one or more embodiments, a transparent electrode may include the graphene-based laminate.

According to one or more embodiments, an electronic device may include the transparent electrode.

### BRIEF DESCRIPTION OF THE DRAWINGS

The patent or application file contains at least one drawing executed in color. Copies of this patent or patent application publication with color drawing(s) will be provided by the Office upon request and payment of the necessary fee. These and/or other aspects will become apparent and more readily appreciated from the following description of the embodiments, taken in conjunction with the accompanying drawings in which:

FIG. 1 is a schematic diagram of a graphene-based laminate according to an embodiment;

FIG. 2 is a schematic diagram illustrating procedures of a method of preparing a graphene-based laminate, according to an embodiment;

FIG. 3 is a view illustrating a color change of an MoO₃ solution between before and after adding H₂O₂ to the MoO₃ solution in a graphene-based laminate prepared according to Example 7;

FIG. 4 is a view illustrating color changes of an MoO₃ solution after adding H₂O₂ to the MoO₃ solution and stirring the solution at a speed of 250 rpm at 70° C. for 1, 3, 5, 8, 10, 12, 14, 17, 19, 24, 34, 41, and 47 hours in the graphene-based laminate prepared according to Example 7;

FIG. 5 is a view illustrating contact angles of MoO₃ solutions with surfaces of the graphene layers each formed on one surface of each of substrates of the graphene-based laminates prepared according to Examples 1 and 6 to 8 and Comparative Examples 3 to 5, as measured using an optical contact angle meter;

FIG. 6 is a graph illustrating sheet resistance results of a graphene-based laminate prepared according to Example 7 in which MoO₃ was used and a graphene-based laminate prepared according to Comparative Example 1 before and after adding H₂O₂ to the MoO3 solution;

FIG. 7 is a graph illustrating sheet resistance results of a graphene-based laminate prepared according to Example 7 after adding H₂O₂ to the MoO₃ solution and stirring the solution at 70° C. at a speed of 250 rpm for 1, 3, 5, 8, 10, 12, 14, 17, 19, 24, 34, 41, and 47 hours;

FIG. 8 is a graph illustrating sheet resistance results of graphene-based laminates prepared according to Examples 1 and 6 to 8 and Comparative Examples 1 and 3 to 5;

FIG. 9 is a graph illustrating sheet resistance results of graphene-based laminates prepared according to Examples 9 to 13 and Comparative Examples 1 and 6;

FIG. 10 is a schematic diagram of an organic light-emitting device according to an embodiment; and

FIG. 11 is a schematic diagram of a back-gated field-effect transistor (FET) according to an embodiment.

### DETAILED DESCRIPTION

Reference will now be made in detail to embodiments which are illustrated in the accompanying drawings, wherein like reference numerals refer to like elements throughout. The embodiment presented herein are all exemplary, and thus, these embodiments may have different forms and should not be construed as being limited to the descriptions set forth herein. As used herein, the term “and/or” includes any and all combinations of one or more of the associated listed items. Expressions such as “at least one of,” when preceding a list of elements, modify the entire list of elements and do not modify the individual elements of the list.

Hereinafter, a graphene-based laminate, a method of preparing the same, and a transparent electrode and an electronic device including the graphene-based laminate according to exemplary embodiments will be described in detail.

Throughout the specification, the term “include” an element do not preclude the other elements but may further include an element unless otherwise stated.

Throughout the specification, it will be understood that when one element, is referred to as being “on” another element, it can be directly on the other element, or intervening elements may also be present therebetween.

As used herein, the “graphene” refers to a polycyclic aromatic carbon compound arranged on a plane and formed of a plurality of carbon atoms connected via covalent bonds (sp² bonds) in a single layer or multilayers. The carbon atoms connected via the covalent bonds constitute 6-membered carbon rings, but the graphene may further include 5-membered carbon rings and/or 7-membered carbon rings.

Throughout the specification, the “graphene” refers to “pristine graphene” having a surface to which functional groups are not attached.

The term “doping”, as used herein, refers to generating a carrier by transferring electrons to a part of a π orbit of a conjugated system or removing electrons therefrom to provide conductivity to the conjugated compound such as a polycyclic aromatic carbon compound. In other words, via a process of adding new electrons to the conjugated system having a double bond or removing electrons therefrom, an unbalance caused in hole molecules changes an electron orbit to an open type to allow electrons to move. In this case, the process of adding new electrons or removing electrons is referred to as “doping”.

A graphene-based laminate according to an embodiment includes a substrate, a graphene layer formed of graphene and disposed on at least one surface of the substrate, and a metal oxide layer disposed on at least one surface of the graphene layer. Here, the metal oxide layer includes a metal oxide having a greater work function than that of graphene, and the metal oxide layer includes the metal oxide in an amount of 1 μg to 1 mg per unit area of 1 cm² of the graphene layer.

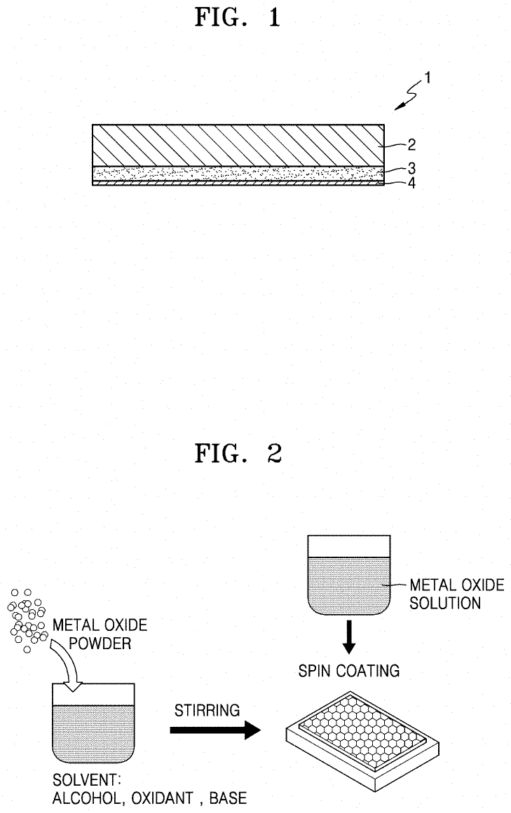

FIG. 1 is a schematic diagram of a graphene-based laminate 1 according to an embodiment.

Referring to FIG. 1, the graphene-based laminate 1 according to the embodiment includes a substrate 2, a graphene layer 3 disposed on one surface of the substrate 2, and a metal oxide layer 4 disposed on one surface of the graphene layer 3.

In the graphene-based laminate 1 according to an embodiment, the graphene layer 3 may be doped with the metal oxide by the metal oxide layer 4 disposed on at least one surface of the graphene layer 3. The graphene-based laminate 1 doped with the metal oxide may have a lower resistance of the graphene layer 3 due to easier hole doping in comparison with a graphene-based laminate which does not include a metal oxide layer. Thus, the graphene-based laminate 1 doped with the metal oxide may have improved conductivity since electrons move from the graphene layer 3 to the metal oxide layer 4 having a greater work function.

In the graphene-based laminate 1 according to an embodiment, the metal oxide layer 4 may include a metal oxide in an amount of 1 μg to 1 mg per unit area of 1 cm² of the graphene layer 3. This amount of the metal oxide per unit area of 1 cm² of the graphene layer 3 included in the metal oxide layer 4 may be obtained by a formula

[(density of the metal oxide (g/cm³))×(thickness of the metal oxide (cm))×(area of the metal oxide layer 4 based on a total area of the graphene layer 3(%))]/100.

For example, the thickness of the metal oxide (cm) and the area of the metal oxide layer 4 based on the total area of the graphene layer 3 (%) may be measured by a field ion microscope, measured by depth profiling using X-ray photoelectron spectroscopy (XPS), or obtained by using an analysis device such as a scanning electron microscope (SEM) and a high resolution transmission electron microscope (HRTEM). However, the embodiment is not limited thereto, and any method of measuring an average thickness well known in the art may also be used. The graphene-based laminate 1 according to the embodiment may efficiently lower sheet resistance values.

According to an embodiment, the metal oxide layer 4 may have a thickness of from 1 nm to 200 nm, and occupy an area of 3% to 100% of the total area of the graphene layer 3. When the graphene-based laminate 1 includes the metal oxide layer 4 having a thickness and an area within the ranges described above, a sheet resistance value may be lowered and a sheet resistance reduction ratio may efficiently be increased.

The metal oxide may include MoO₃, V₂O₅, CrO₃, NiO, WO₃, or any combination thereof. For example, the metal oxide may include MoO₃, WO₃, or any combination thereof. The metal oxide may have excellent properties in terms of hole doping and electrical conductivity.

The graphene layer 3 may be a single layer.

The substrate may be a transfer substrate.

The substrate may include polyethylene terephthalate, polycarbonate, polyimide, polyethylene naphthalate, or a glass substrate. The substrate may be used as a substrate of a transparent electrode.

The graphene-based laminate 1 may have a sheet resistance reduction ratio of 10% or greater, and the sheet resistance reduction ratio may be obtained by Equation 1 below.

Sheet resistance reduction ratio (%)=Absolute value of {[(sheet resistance value of graphene-based laminate not including metal oxide layer−sheet resistance value of graphene-based laminate including metal oxide layer)/sheet resistance value of graphene-based laminate not including metal oxide layer]×100} [Equation 1]

For example, the graphene-based laminate 1 may have a lowest sheet resistance value of 180 Ω/sq.

The graphene-based laminate 1 may further include a surface coating layer (not shown in FIG. 1) formed on the metal oxide layer 4. Since the surface coating layer may screen moisture of the metal oxide layer 4 and/or impurities having charges, a graphene-based laminate 1 including the same may have a decreased sheet resistance value and maintain an increased sheet resistance reduction ratio.

A method of preparing a graphene-based laminate according to an embodiment may include: preparing a metal oxide solution by adding a metal oxide to a mixture of an alcohol solvent and an oxidant and stirring the mixture; and preparing a graphene-based laminate by forming a metal oxide layer on a graphene layer formed on at least one surface of a substrate by coating the metal oxide solution on the graphene layer.

Since a method of depositing a metal oxide on a graphene layer is generally performed at a high temperature or in a vacuum, a lot of time, costs, and energy are consumed.

According to the above method of preparing the graphene-based laminate, mass production is possible regardless of sizes of samples, wetting properties of solutions are improved, and economical efficiency may be improved.

A base may further be added to the metal oxide solution. The base may include, for example, NH₄OH.

FIG. 2 is a schematic diagram illustrating procedures of a method of preparing a graphene-based laminate according to an embodiment.

Referring to FIG. 2, a metal oxide solution is first prepared by adding metal oxide powder to a mixture of an alcohol solvent and an oxidant and stirring the mixture.

The metal oxide may include MoO₃, V₂O₅, CrO₃, NiO, WO₃, or any combination thereof. For example, the metal oxide may include MoO₃, WO₃, or any combination thereof. The metal oxide may be in the form of powder. The metal oxide has excellent properties in terms of hole doping and electrical conductivity.

The alcohol solvent may include methanol, ethanol, propanol, butanol, isopropanol, or any mixture thereof. The alcohol solvent is a solvent covering hydrophobicity of the graphene layer.

The metal oxide may be contained in an amount of 1% by weight to 5% by weight based on the metal oxide solution. For example, the metal oxide may be contained in an amount of 2% by weight to 5% by weight based on the metal oxide solution. For example, the metal oxide may be contained in an amount of 3% by weight to 5% by weight based on the metal oxide solution. For example, the metal oxide may be contained in an amount of 4% by weight to 5% by weight based on the metal oxide solution. When the amount of the metal oxide is within these ranges, a sheet resistance reduction ratio of 10% or greater and a reduced sheet resistance value may be obtained.

The oxidant may include H₂O₂. The metal oxide solution has an unstable oxidation number before adding the oxidant thereto. After adding the oxidant, the metal oxide of the metal oxide solution having the unstable oxidation number is oxidized to allow the metal oxide solution to have a stable oxidation number. By using such a metal oxide solution having the stable oxidation number, the prepared graphene-based laminate may have a reduced sheet resistance value.

A volume ratio of the metal oxide solution to the oxidant may be from 1:1 to 9:1.

A contact angle of the metal oxide solution with the surface of the graphene layer formed on one surface of the substrate may be 20° or less.

When the volume ratio of the metal oxide solution to the oxidant and the contact angle of the metal oxide solution with the surface of the graphene layer formed on one surface of the substrate are within the ranges above, wetting properties of the metal oxide solution with regard to the surface of the graphene layer formed on the one surface of the substrate may be improved.

The stirring may be performed at a temperature of from room temperature to 100° C. for 1 hour to 24 hours. For example, the stirring may be performed at a temperature of from 50° C. to 100° C. for 5 hours to 24 hours. For example, the stirring may be performed at a temperature of from 70° C. to 100° C. for 6 hours to 12 hours. When the stirring temperature and stirring time of the metal oxide solution are within the ranges above, the graphene-based laminate using the same may have a reduced sheet resistance value.

The coating may be performed by spin coating.

A transparent electrode according to an embodiment may include the graphene-based laminate.

An electronic device according to an embodiment may include the transparent electrode.

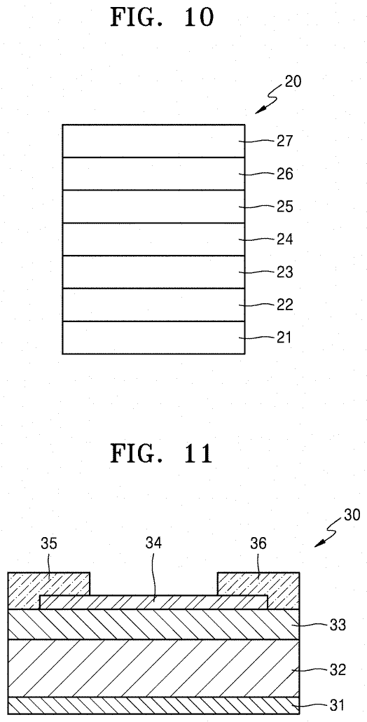

FIG. 10 is a schematic diagram of an organic light-emitting device 20 according to an embodiment.

As illustrated in FIG. 10, the organic light-emitting device 20 includes a substrate (not shown), a first electrode 21, a hole injection layer 22, a hole transport layer 23, an emission layer 24, an electron transport layer 25, an electron injection layer 26, and a second electrode 27.

The first electrode 21 may be an anode or a cathode. For example, the first electrode 21 may be an anode. In this regard, the substrate may be any substrate (not shown) commonly used in organic light-emitting devices, for example, a glass substrate or a transparent plastic substrate having excellent mechanical strength, thermal stability, transparency, surface smoothness, ease of handling, and water resistance. Indium tin oxide (ITO), indium zinc oxide (IZO), tin oxide (SnO₂), zinc oxide (ZnO), Al, Ag, or Mg may be used to form the first electrode 21, and the first electrode 21 may be formed as a transparent electrode or a reflective electrode.

The first electrode 21 may be a transparent electrode including the above-described graphene-based laminate. The transparent electrode may have a significantly decreased sheet resistance value and a considerably increased sheet resistance reduction ratio in comparison with transparent electrodes including only graphene.

Next, the hole injection layer 22 may be formed on the first electrode 21 by using various methods such as vacuum deposition, spin coating, casting, or Langmuir-Blodgett (LB) technique.

When the hole injection layer 22 is formed by vacuum deposition, deposition conditions may appropriately be selected from a deposition temperature of 100° C. to 500° C., a vacuum pressure of 10⁻⁸ torr to 10⁻³ torr, and a deposition rate of about 0.01 Å/sec to about 100 Å/sec although the deposition conditions may vary according to a compound used to form the hole injection layer 22 and a structure and thermal properties of the hole injection layer 22 to be formed.

When the hole injection layer 22 is formed by spin coating, coating conditions may appropriately be selected from a coating rate of about 2000 rpm to about 5000 rpm and a heat treatment temperature of about 80° C. to about 200° C. to remove a solvent after coating although the coating conditions may vary according to a compound used to form the hole injection layer 22 and a structure and thermal properties of the hole injection layer 22 to be formed.

Examples of the compound used to form the hole injection layer 22 may include a phthalocyanine compound such as copperphthalocyanine, 4,4′,4″-tris(3-methylphenylphenylamino) triphenylamine (m-MTDATA), N,N′-di(1-naphthyl)-N,N′-diphenylbenzidine (NPB), TDATA, 2T-NATA, Polyaniline/Dodecylbenzenesulfonic acid (Pani/DBSA), Poly(3,4-ethylenedioxythiophene)/Poly(4-styrenesulfonate) (PEDOT/PSS), Polyaniline/Camphor sulfonic acid (Pani/CSA), or Polyaniline/Poly(4-styrenesulfonate) (PANI/PSS), without being limited thereto.

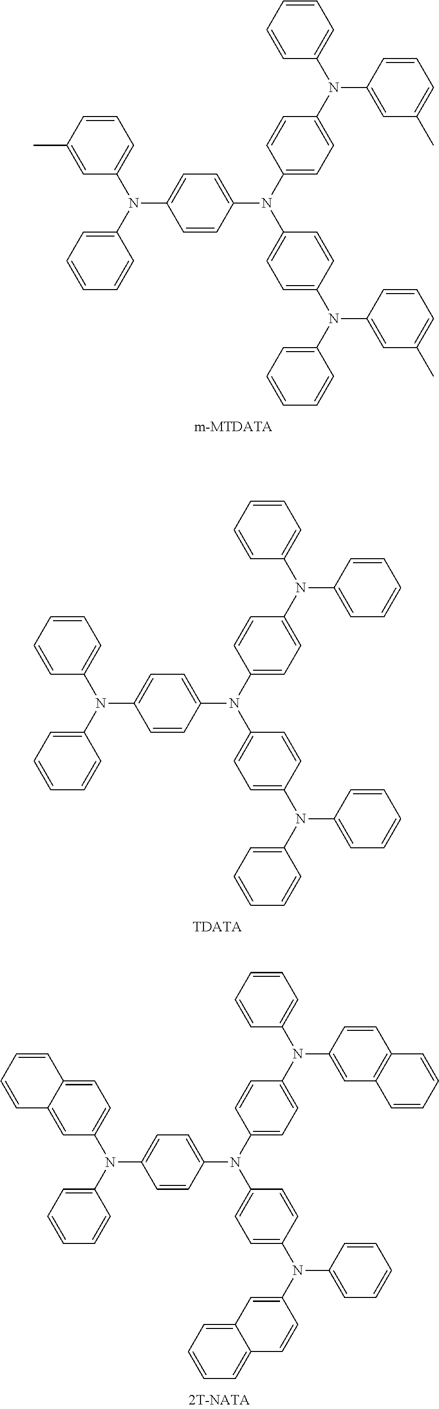

A thickness of the hole injection layer 22 may be from about 100 Å to about 10000 Å, for example, from about 100 Å to about 1000 Å. When the thickness of the hole injection layer 22 satisfies the above range, the hole injection layer 22 may have excellent hole injecting properties without an increase in driving voltage.

Subsequently, the hole transport layer 23 may be formed on the hole injection layer 22 by using various methods such as vacuum deposition, spin coating, casting, or an Langmuir-Blodgett (LB) technique. When the hole transport layer 23 is formed by vacuum deposition and spin coating, deposition conditions and coating conditions may be similar to those for the formation of the hole injection layer 22 although the deposition conditions and coating conditions may vary according to a compound used to form the hole transport layer 23.

Examples of the compound used to form the hole transport layer 23 may include a carbazole derivative such as N-phenylcarbazole and polyvinyl carbazole and an amine derivative having an aromatic condensed ring such as N,N′-di(1-naphthyl)-N,N′-diphenylbenzidine (NPB) or N,N′-bis(3-methylphenyl)-N,N′-diphenyl-[1,1-biphenyl]-4,4′-diamine (TPD), without being limited thereto.

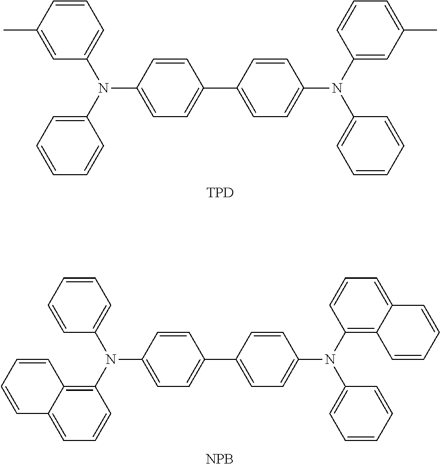

A thickness of the hole transport layer 23 may be from about 50 Å to about 1000 Å, for example, from about 100 Å to about 600 Å. When the thickness of the hole transport layer 23 satisfies the above range, excellent hole transporting properties may be obtained without a substantial increase in driving voltage.

Subsequently, the emission layer 24 may be formed on the hole transport layer 23 by using various methods such as vacuum deposition, spin coating, casting, or an LB technique. When the emission layer 24 is formed by vacuum deposition and spin coating, deposition conditions and coating conditions may be similar to those for the formation of the hole injection layer 22 although the deposition conditions and coating conditions may vary according to a compound used to form the emission layer 24.

The emission layer 24 may be formed of, for example, any known host or dopant. In the case of the dopant, both of fluorescent dopants and phosphorescent dopants well known in the art may be used.

Examples of the known host may include tris-(8-quinolinorate)aluminum (Alq3), 4,4′-N,N′-dicarbazole-biphenyl (CBP), poly(n-vinylcarbazole) (PVK), 9,10-di(naphthalene-2-yl)anthracene (ADN), 1,3,5-tris(N-phenylbenzimidazole-2-yl)benzene (TPBI), 3-tert-butyl-9,10-di(naphth-2-yl) anthracene (TBADN), E3, or distyrylarylene (DSA), without being limited thereto.

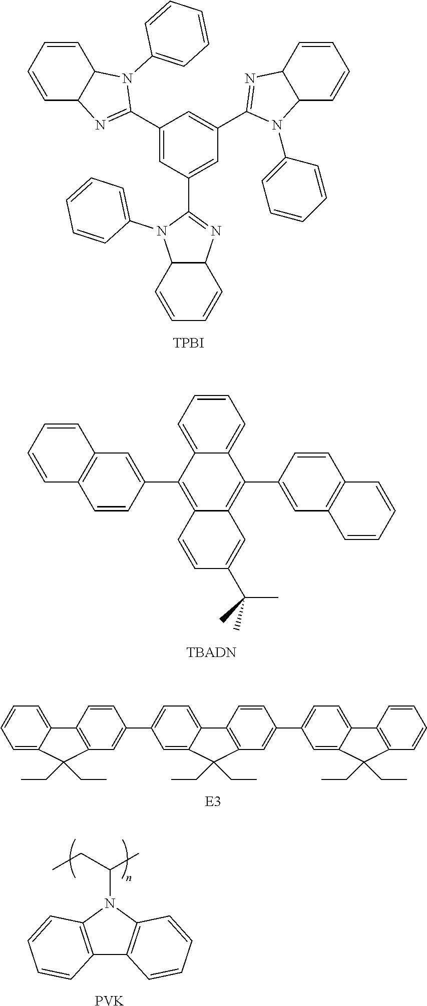

Meanwhile, examples of known red dopants may include, but are not limited to, PtOEP, Ir(piq)₃, Btp₂Ir(acac), and DCJTB.

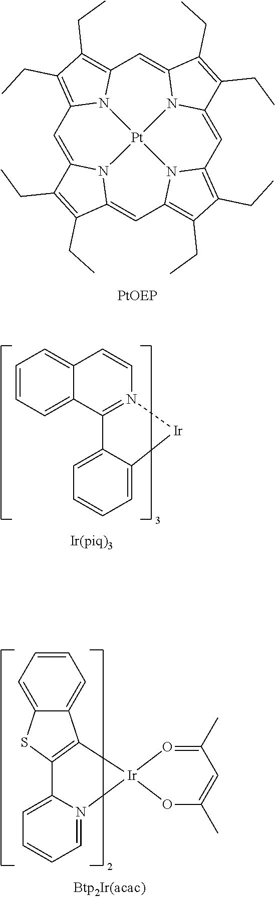

Also, examples of known green dopants may include, but are not limited to, Ir(ppy)₃ (ppy=phenylpyridine), Ir(ppy)₂(acac), Ir(mpyp)₃, and C545T.

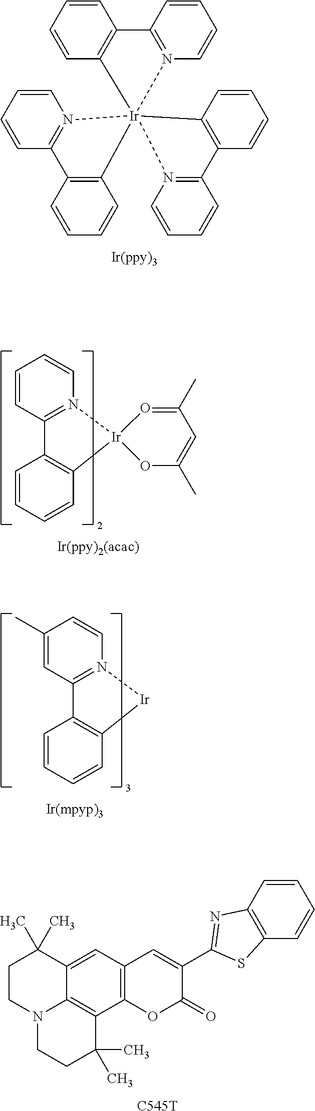

Meanwhile, examples of known blue dopants may include, but are not limited to, F₂Irpic, (F₂ppy)₂Ir(tmd), Ir(dfppz)₃, ter-fluorene, 4,4′-bis(4-diphenylaminostyryl) biphenyl (DPAVBi), and 2,5,8,11-tetra-t-bytylperylene (TBP).

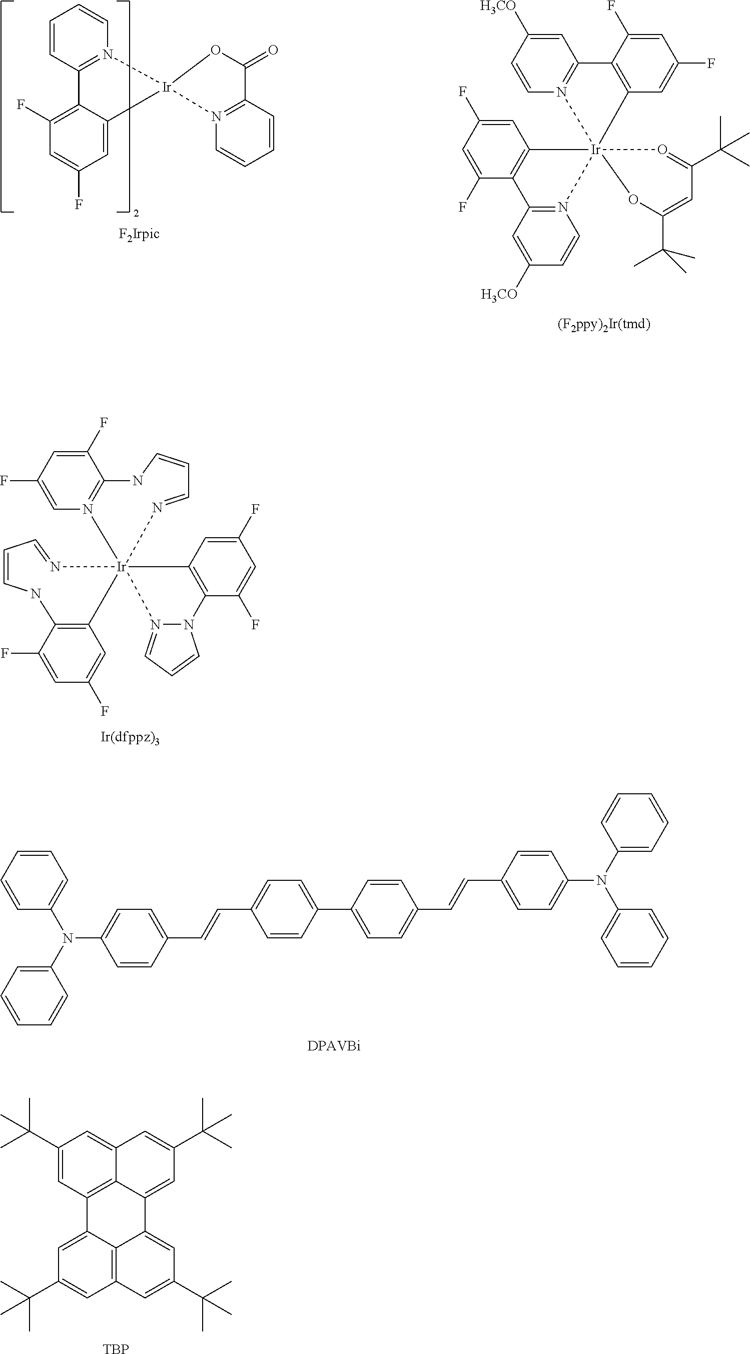

An amount of the dopant may be from 0.1 parts by weight to 20 parts by weight, for example, 0.5 parts by weight to 12 parts by weight, based on 100 parts by weight of materials used to form the emission layer 24 (i.e., a total weight of the host and the dopant is referred to as 100 parts by weight). When the amount of the dopant satisfies the above range, a concentration quenching phenomenon may substantially be prevented.

A thickness of the emission layer 24 may be from about 100 Å to about 1000 Å, for example, from about 200 Å to about 600 Å. When the thickness of the emission layer 24 satisfies the above ranges, excellent light emitting properties may be obtained without a substantial increase in driving voltage.

When the emission layer 24 includes a phosphorescent dopant, a hole blocking layer (HBL) (not shown in FIG. 10) may be formed on the emission layer 24 to prevent diffusion of triplet excitons or holes into the electron transport layer 25 (not shown). In this regard, a material used to form the hole blocking layer is not particularly limited and any known hole blocking materials may be selected. For example, an oxadiazole derivative, a triazole derivative, a phenanthroline derivative, Balq, or BCP may be used.

A thickness of the hole blocking layer may be from about 50 Å to about 1000 Å, for example, from about 100 Å to about 300 Å. When the thickness of the hole blocking layer is within the range, diffusion of triplet excitons or holes into the electron transport layer 25 may be prevented without a substantial increase in driving voltage.

Subsequently, the electron transport layer 25 is formed by using various methods such as vacuum deposition, spin coating, or casting. When the electron transport layer 25 is formed by vacuum deposition and spin coating, deposition conditions and coating conditions may be similar to those for the formation of the hole injection layer 22 although the deposition conditions and coating conditions may vary according to a compound used to form the electron transport layer 25.

Examples of the compound used to form the electron transport layer 25 may include a quinolone derivative, particularly, known materials such as tris(8-hydroxyquinolinato)aluminium (Alq₃), TAZ, or Balq, without being limited thereto.

A thickness of the electron transport layer 25 may be from about 100 Å to about 1000 Å, for example, from about 100 Å to about 500 Å. When the thickness of the electron transport layer 25 satisfies the above ranges, excellent electron transporting properties may be obtained without a substantial increase in driving voltage.

Also, the electron injection layer 26 including a material facilitating injection of electrons from the second electrode 27 may be laminated on the electron transport layer 25.

Any known electron injecting materials such as LiF, NaCl, CsF, Li₂O, or BaO may be used to form the electron injection layer 26. Deposition conditions and coating conditions may be similar to those for the formation of the hole injection layer 22 although the deposition conditions and coating conditions may vary according to a compound used to form the electron injection layer 26.

A thickness of the electron injection layer 26 may be from about 1 Å to about 100 Å, for example, from about 5 Å to about 90 Å. When the thickness of the electron injection layer 26 is within the ranges above, excellent electron injecting properties may be obtained without a substantial increase in driving voltage.

Finally, the second electrode 27 may be formed on the electron injection layer 26 by vacuum deposition, sputtering, or the like. The second electrode 27 may be used as a cathode or an anode. A metal, an alloy, or an electrically conductive compound having a low work function, or any mixture thereof may be used to form the second electrode 27. Examples thereof may include lithium (Li), magnesium (Mg), aluminum (Al), aluminum-lithium (Al—Li), calcium (Ca), magnesium-indium (Mg—In), and magnesium-silver (Mg—Ag). In addition, a transparent cathode formed of ITO or IZO may be used to manufacture a top emission-type organic light-emitting device.

The organic light-emitting device 20 may be applied to various types of flat panel display apparatuses, such as passive matrix organic light-emitting apparatuses and active matrix organic light-emitting apparatuses. For example, when applied to active matrix organic light-emitting devices, the first electrode 21 formed on the substrate, as a pixel electrode, may be electrically connected to a source electrode or a drain electrode. Also, the organic light-emitting device 20 may be applied to a flat panel display apparatus having a double-sided screen.

In addition, the organic light-emitting device 20 may include a plurality of organic layers, and at least one of the organic layers may be formed by a deposition method or a wet method of coating a compound prepared in a solution.

An electronic device including the graphene-based laminate according to the above embodiment may be, for example, a field effect transistor (FET). However, shapes or types thereof are not particularly limited but may be appropriately modified according to the uses thereof. The TFT may be, for example, a back-gated FET.

FIG. 11 is a schematic diagram of a back-gated FET 30 according to an embodiment.

As illustrated in FIG. 11, in the back-gated FET 30, an Si-doped substrate 32 as a back gate and an insulator layer 33 are sequentially laminated on a back gate contact surface 31. A graphene-based laminate channel layer 34 is in contact therewith between a source electrode 35 and a drain electrode 36.

In this regard, a gap between the source electrode 35 and the drain electrode 36 may be determined according to the use of the FET. For example, the gap between the source electrode 35 and the drain electrode 36 may be from 0.1 μm to 1 mm, for example, 1 μm to 100 μm, or 5 μm to 100 μm.

The source electrode 35 and the drain electrode 36 may be formed of any conductive material such as platinum, gold, silver, nickel, chromium, copper, iron, tin, antimony lead, tantalum, indium, palladium, tellurium, rhenium, iridium, aluminum, ruthenium, germanium, molybdenum, tungsten, tin antimony oxide, indium tin oxide (ITO), fluorine-doped zinc oxide, zinc, carbon, graphite, glasslike carbon, silver paste and carbon paste, lithium, beryllium, sodium, magnesium, potassium, calcium, scandium, titanium, manganese, zirconium, gallium, niobium, an sodium-potassium alloy, a magnesium/copper mixture, a magnesium/silver mixture, a magnesium/aluminum mixture, a magnesium/indium mixture, an aluminum/aluminum oxide mixture, a lithium/aluminum mixture, without limitation. When these conductive materials are used, the electrodes may be formed by sputtering or vacuum deposition.

The source electrode 35 and the drain electrode 36 may be formed using a fluidic electrode material such as a solution, paste, ink, or dispersion including the conductive material. As a dispersion including metal fine particles, any known conductive paste may be used, for example, a dispersion including metal fine particles having a particle diameter of 0.5 nm to 50 nm, for example, 1 nm to 10 nm. Examples of the metal fine particles may include fine particles of platinum, gold, silver, nickel, chromium, copper, iron, tin, antimony lead, tantalum, indium, palladium, tellurium, rhenium, iridium, aluminum, ruthenium, germanium, molybdenum, tungsten, and zinc.

A width and a length of the graphene-based laminate channel layer 34 may be from 20 nm to 20 μm, respectively. However, the width and the length are not limited thereto, and may appropriately be adjusted according to the uses thereof.

The insulator layer 33 may be formed of any material having electrical insulating properties and available as a thin film, such as metal oxide (including silicon oxide), metal nitride (including silicon nitride), a polymer, or a low-molecular organic material having an electrical resistivity of 10 Ω·cm or greater at room temperature, without limitation. For example, an inorganic oxide film having a high dielectric constant may be used.

Examples of inorganic oxide forming the inorganic oxide film may include silicon oxide, aluminum oxide, and hafnium oxide, and a thickness of the inorganic oxide film may be from about 100 nm to about 300 nm. In addition, the inorganic oxide may include silicon nitride, aluminum nitride, or the like.

The insulator layer 33 using an organic compound may include polyimide, polyamide, polyester, polyacrylate, a photoradical polymerization system, photo-curable resin of a photo-cationic polymerization system, a copolymer including acrylonitrile, polyvinyl phenol, polyvinyl alcohol, novolac resin, or cyanoethylfluorane, or the like.

Other examples thereof include wax, polyethylene, polychloropyrene, polyethylene terephthalate, polyoxymethylene, polyvinyl chloride, polyvinylidene fluoride, polysulfone, polycarbonate, polyimidecyanoethyl pullulan, poly(vinylphenol) (PVP), poly(methylmethacrylate) (PMMA), polycarbonate (PC), polystyrene (PS), polyolefin, polyacrylamide, poly(acrylic acid), novolac resin, resol resin, polyimide, polyxylene, and epoxy resin. In addition to these resins, a polymer having a high dielectric constant such as pullulan may be used.

The insulator layer 33 may be a mixed layer in which the inorganic or organic materials described above are used in combination or a stacked layer thereof. In this case, performance of devices may be controlled by mixing or stacking a material having a high dielectric constant and a material having water repellency.

The insulator layer 33 may be formed by using a dry process such as a vacuum vapor deposition method, a molecular beam epitaxial growth method, an ion cluster beam method, a low energy ion beam method, an ion plating method, a chemical vapor deposition (CVD) method, a sputtering method, or an atmospheric-pressure plasma method, or a wet process such as a coating method, e.g., a spray coating method, a spin coating method, a blade coating method, a dip coating method, a casting method, a roll coating method, a bar coating method, or a die coating method or a patterning method, e.g., printing or inkjet printing which may appropriately be used according to materials. As the wet process, a method of applying and drying a liquid obtained by dispersing fine particles of an inorganic oxide in an organic solvent or water using a dispersion assisting agent, such as a surfactant, when required, or a so-called sol-gel method in which an oxide precursor, e.g., an alkoxide solution, is applied and dried, may be used.

Since the Si-doped substrate 32, as the back gate, has improved conductivity, contact resistance to the source electrode 35 and the drain electrode 36 may be reduced.

Meanwhile, the above-mentioned graphene-based laminate may also be applied to solar cells, sensors, or the like in addition to the above-mentioned organic light-emitting devices and FETs.

Hereinafter, one or more embodiments will be described in detail with reference to the following examples and comparative examples. These examples and comparative examples are not intended to limit the purpose and scope of the embodiments.

### EXAMPLES: PREPARATION OF GRAPHENE-BASED LAMINATE

### Example 1: Preparation of Graphene-Based Laminate

A single layer (about 0.34 nm) of graphene was grown on a copper (Cu) foil having a thickness of 35 μm by a rapid thermal CVD device using a halogen lamp heater. A thermal tape was attached to surface of the graphene layer, and the Cu foil was etched by immersing the graphene layer in an acid compound. Subsequently, a Tape/graphene layer laminate was transferred to a polyethylene terephthalate (PET) substrate. Separately, MoO₃ oxide powder (Sigma-Aldrich, product number: 203815), 7 mL of isopropylalcohol, and 7 mL of H₂O₂ (30% in water), as an oxidant, were mixed and stirred at 70° C. for 6 hours at a speed of 250 rpm to obtain an MoO₃ solution. An amount of the MoO₃ oxide was 1% by weight based on the MoO₃ solution. A volume ratio of the MoO₃ solution to the H₂O₂ oxidant was 1:1. The obtained MoO₃ solution was spin-coated on the graphene layer of the graphene layer/PET substrate to prepare a graphene-based laminate having the MoO₃ layer. An area of the MoO₃ layer formed on the graphene layer was 9.36%.

### Example 2: Preparation of Graphene-Based Laminate

A graphene-based laminate was prepared in the same manner as in Example 1, except that the amount of the MoO₃ oxide was 2% by weight instead of 1% by weight. An area of the MoO₃ layer occupied on the graphene layer was 52.37%.

### Example 3: Preparation of Graphene-Based Laminate

A graphene-based laminate was prepared in the same manner as in Example 1, except that the amount of the MoO₃ oxide was 3% by weight instead of 1% by weight. An area of the MoO₃ layer occupied on the graphene layer was 61.40%.

### Example 4: Preparation of Graphene-Based Laminate

A graphene-based laminate was prepared in the same manner as in Example 1, except that the amount of the MoO₃ oxide was 4% by weight instead of 1% by weight. An area of the MoO₃ layer occupied on the graphene layer was 100%.

### Example 5: Preparation of Graphene-Based Laminate

A graphene-based laminate was prepared in the same manner as in Example 1, except that the amount of the MoO₃ oxide was 5% by weight instead of 1% by weight. An area of the MoO₃ layer occupied on the graphene layer was 100%.

### Example 6: Preparation of Graphene-Based Laminate

A graphene-based laminate was prepared in the same manner as in Example 1, except that the volume ratio of the MoO₃ solution to the H₂O₂ oxidant was 3:1 instead of 1:1.

### Example 7: Preparation of Graphene-Based Laminate

A graphene-based laminate was prepared in the same manner as in Example 1, except that the volume ratio of the MoO₃ solution to the H₂O₂ oxidant was 6:1 instead of 1:1.

### Example 8: Preparation of Graphene-Based Laminate

A graphene-based laminate was prepared in the same manner as in Example 1, except that the volume ratio of the MoO₃ solution to the H₂O₂ oxidant was 9:1 instead of 1:1.

### Example 9: Preparation of Graphene-Based Laminate

A graphene-based laminate in which a WO₃ layer is formed on the graphene layer of the graphene layer/PET substrate was prepared in the same manner as in Example 1, except that an WO₃ oxide was used instead of the MoO₃ oxide, an amount of the WO₃ oxide was 1% by weight based on a WO₃ solution, and a volume ratio of the WO₃ solution to the H₂O₂ oxidant was 1:1.

### Example 10: Preparation of Graphene-Based Laminate

A graphene-based laminate in which a WO₃ layer is formed on the graphene layer of the graphene layer/PET substrate was prepared in the same manner as in Example 1, except that an WO₃ oxide was used instead of the MoO₃ oxide, an amount of the WO₃ oxide was 2% by weight based on the WO₃ solution, and a volume ratio of the WO₃ solution to the H₂O₂ oxidant was 1:1.

### Example 11: Preparation of Graphene-Based Laminate

A graphene-based laminate in which a WO₃ layer is formed on the graphene layer of the graphene layer/PET substrate was prepared in the same manner as in Example 1, except that an WO₃ oxide was used instead of the MoO₃ oxide, an amount of the WO₃ oxide was 3% by weight based on the WO₃ solution, and a volume ratio of the WO₃ solution to the H₂O₂ oxidant was 1:1.

### Example 12: Preparation of Graphene-Based Laminate

A graphene-based laminate in which a WO₃ layer is formed on the graphene layer of the graphene layer/PET substrate was prepared in the same manner as in Example 1, except that an WO₃ oxide was used instead of the MoO₃ oxide, an amount of the WO₃ oxide was 4% by weight based on the WO₃ solution, and a volume ratio of the WO₃ solution to the H₂O₂ oxidant was 1:1.

### Example 13: Preparation of Graphene-Based Laminate

A graphene-based laminate in which a WO₃ layer is formed on the graphene layer of the graphene layer/PET substrate was prepared in the same manner as in Example 1, except that an WO₃ oxide was used instead of the MoO₃ oxide, an amount of the WO₃ oxide was 5% by weight based on the WO₃ solution, and a volume ratio of the WO₃ solution to the H₂O₂ oxidant was 1:1.

### Comparative Example 1: Preparation of Graphene-Based Laminate

A graphene-based laminate was prepared in the same manner as in Example 1, except that the MoO₃ layer was not formed on the graphene layer of the graphene layer/PET substrate.

### Comparative Example 2: Preparation of Graphene-Based Laminate

A graphene-based laminate was prepared in the same manner as in Example 1, except that the amount of the MoO₃ oxide was 0.5% by weight instead of 1% by weight based on the MoO₃ solution.

### Comparative Example 3: Preparation of Graphene-Based Laminate

A graphene-based laminate was prepared in the same manner as in Example 4, except that the volume ratio of the MoO₃ solution to the H₂O₂ oxidant was 1:3 instead of 1:1.

### Comparative Example 4: Preparation of Graphene-Based Laminate

A graphene-based laminate was prepared in the same manner as in Example 4, except that the volume ratio of the MoO₃ solution to the H₂O₂ oxidant was 1:6 instead of 1:1.

### Comparative Example 5: Preparation of Graphene-Based Laminate

A graphene-based laminate was prepared in the same manner as in Example 4, except that the volume ratio of the MoO₃ solution to the H₂O₂ oxidant was 1:9 instead of 1:1.

### Comparative Example 6: Preparation of Graphene-Based Laminate

A graphene-based laminate in which a WO₃ layer is formed on the graphene layer of the graphene layer/PET substrate was prepared in the same manner as in Example 1, except that an WO₃ oxide was used instead of the MoO₃ oxide, an amount of the WO₃ oxide was 0.5% by weight based on the WO₃ solution, and a volume ratio of the WO₃ solution to the H₂O₂ oxidant was 1:1.

### Analysis Example 1: Observation of Color Change of Metal Oxide Solution

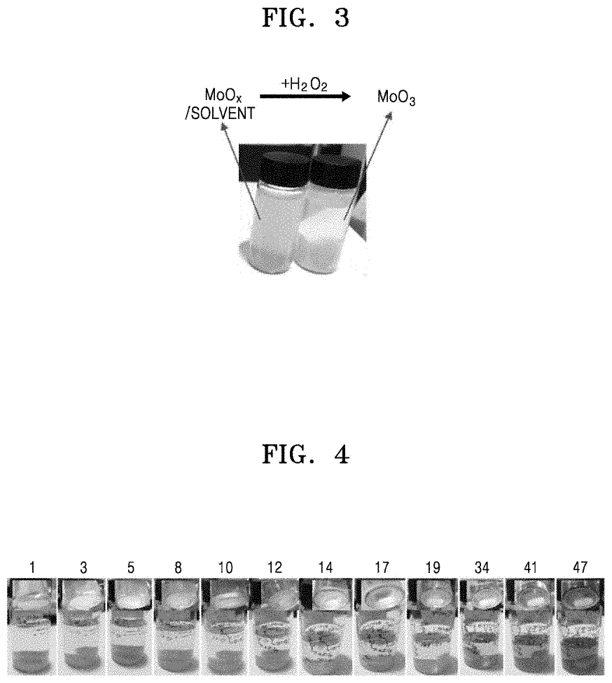

In the graphene-based laminate according to Example 7, color changes of the MoO₃ solution before and after adding H₂O₂ to the MoO₃ solution were evaluated by visual observation. The results are shown in FIG. 3. Referring to FIG. 3, after adding H₂O₂ to the MoO₃ solution, oxidation proceeds in the graphene-based laminate according to Example 7 and the color changed from colorless to yellow. In the graphene-based laminate according to Example 7, color changes of the MoO₃ solution were also evaluated by visual observation after adding H₂O₂ to the MoO₃ solution and stirring the mixture at 70° C. at a speed of 250 rpm for 1, 3, 5, 8, 10, 12, 14, 17, 19, 24, 34, 41, and 47 hours, respectively. The results are shown in FIG. 4. Referring to FIG. 4, in the graphene-based laminate according to Example 7, the color gradually changed from light yellow to dark yellow from 1 hour to 34 hours and from dark yellow to green and from green to blue after 34 hours.

### Analysis Example 2: Optical Microscope—Contact Angle of MoO₃ Solution with Surface of Graphene Layer

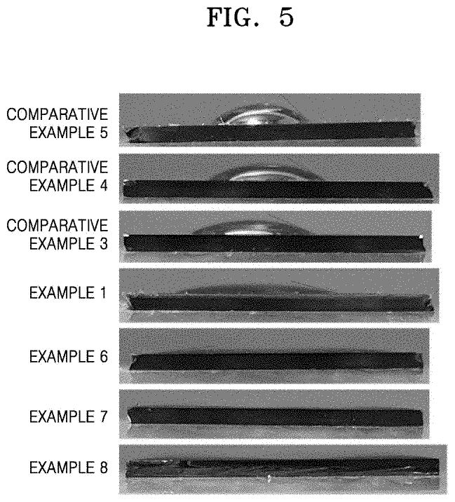

Contact angles of the MoO₃ solutions with the surfaces of the graphene layers formed on one surface of the graphene-based laminates according to Examples 1 and 6 to 8 and Comparative Examples 3 to 5 were measured using an optical contact angle meter. The results are shown in FIG. 5. The contact angle of the MoO₃ solution with the surface of the graphene layer was measured by dropping 1 μL of the MoO₃ solution onto the surface of the graphene layer formed on one surface of the substrate at room temperature using the optical contact angle meter. Referring to FIG. 5, contact angles of the MoO₃ solutions with the surfaces of the graphene layers formed on one surface of the substrates in the graphene-based laminates according to Examples 1 and 6 to 8 were 15.18°, 6.63°, 0°, and 0°, respectively. Contact angles of the MoO₃ solutions with the surfaces of the graphene layers formed on one surface of the substrates in the graphene-based laminates according to Comparative Examples 3 to 5 were 22.48°, 30.93°, and 44.42°.

The contact angles of the MoO₃ solutions with the surfaces of the graphene layers formed on one surface of the graphene-based laminates according to Examples 1 and 6 to 8 were smaller than those of the MoO₃ solutions with the surfaces of the graphene layers formed on one surface of the graphene-based laminates according to Comparative Examples 3 to 5. Thus, it may be confirmed that the MoO₃ solutions have better wetting properties with respect to the surfaces of the graphene layers formed on one surface of the substrates in the graphene-based laminates according to Examples 1 and 6 to 8 than wetting properties of the MoO₃ solutions with respect to the surfaces of the graphene layers formed on one surfaces of the substrates in the graphene-based laminates according to Comparative Examples 3 to 5.

### Evaluation Example 1: Sheet Resistance Value

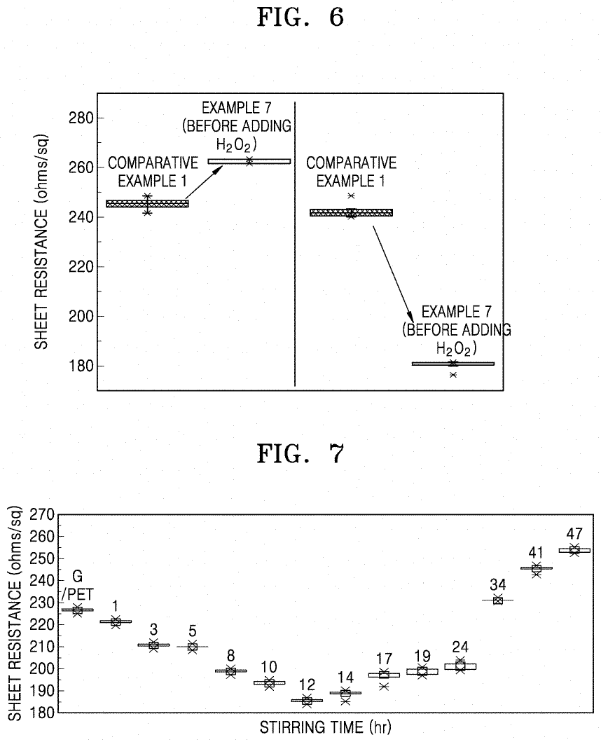

Sheet resistance values of the graphene-based laminate according to Example 7, in which using MoO₃ was used, with respect to the MoO₃ solution were measured before and after adding H₂O₂ in comparison with the graphene-based laminate according to Comparative Example 1. The results are shown in FIG. 6.

Sheet resistance values were measured according to the following method.

A graphene-based laminate sample having a size of 1.2×1.2 cm² and using the MoO₃ solution according to Example 7 and a graphene-based laminate sample having a size of 1.2×1.2 cm² according to Comparative Example 1 were prepared before and after adding H₂O₂. 4 pins of a sheet resistance meter were brought into contact with a top portion of each sample, and voltages were measured at two central pins while supplying a current of 1 mA to the other two pins at both ends.

A 4-point probe (ASRM-200C, DASOL ENG) including TH-tungsten (99.95%) as a pin material and having a pin diameter of 0.5 mm and a pin spacing of 1.591 mm was used as the sheet resistance meter.

Referring to FIG. 6, the graphene-based laminate according to Example 7 using the MoO₃ solution exhibited a greater sheet resistance before adding H₂O₂ than the graphene-based laminate according to Comparative Example 1. It may be considered that MoO₃ (MoOₓ (2<x<3)) having an insufficient oxidation number was generated in the MoO₃ solution before adding H₂O₂. The graphene-based laminate according to Example 7 using the MoO₃ solution exhibited a lower sheet resistance after adding H₂O₂ than the graphene-based laminate according to Comparative Example 1. It may be considered that the MoO₃ solution was stabilized since MoOₓ was oxidized in the MoO₃ solution after adding H₂O₂.

Sheet resistance values of the graphene-based laminate according to Example 7 was measured to the MoO₃ solution after adding H₂O₂ to the MoO₃ solution and stirring the solution at 70° C. at a speed of 250 rpm for 1, 3, 5, 8, 10, 12, 14, 17, 19, 24, 34, 41, and 47 hours, respectively. The results are shown in FIG. 7.

A method of measuring sheet resistance values and a sheet resistance meter were as described above, except that MoO₃ solutions obtained by adding H₂O₂ to the MoO₃ solution of the graphene-based laminate according to Example 7 and stirring the solution at 70° C. at a speed of 250 rpm for 1, 3, 5, 8, 10, 12, 14, 17, 19, 24, 34, 41, and 47 hours was used as samples.

Referring to FIG. 7, when H₂O₂ was added to the MoO₃ solution and the solution was stirred at 70° C. at a speed of 250 rpm from 1 hour to 12 hours in the graphene-based laminate according to Example 7, the sheet resistance values of the graphene-based laminate decreased as the stirring time increased. It may be considered that this result was obtained due to an increase in solubility of the MoO₃ solution. In comparison, when H₂O₂ was added to the MoO₃ solution and the solution was stirred at 70° C. at a speed of 250 rpm from 12 hours to 47 hours in the graphene-based laminate according to Example 7, the sheet resistance values of the graphene-based laminate increased as the stirring time increased.

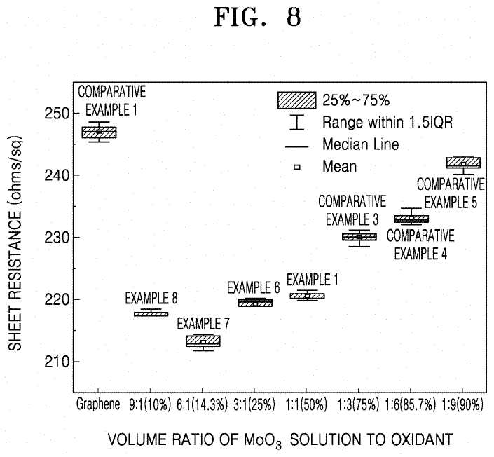

In addition, sheet resistance values of the graphene-based laminates according to Examples 1 and 6 to 8 and Comparative Examples 1 and 3 to 5 were measured. The results are shown in FIG. 8.

A method of measuring sheet resistance values and a sheet resistance meter were as described above, except that the graphene-based laminates according to Examples 1 and 6 to 8 and Comparative Examples 1 and 3 to 5 were used as samples.

Referring to FIG. 8, the graphene-based laminates according to Examples 1 and 6 to 8 showed lower sheet resistance reduction ratios than that of the graphene-based laminate (not including the metal oxide layer) according to Comparative Example 1 by 10% or more. In comparison, the graphene-based laminates according to Comparative Examples 3 to 5 showed lower sheet resistance reduction ratios than the graphene-based laminate (not including the metal oxide layer) according to Comparative Example 1 by 6.5% or less. The sheet resistance reduction ratio is obtained by Equation 1 below.

Sheet resistance reduction ratio (%)=Absolute value of {[(sheet resistance value of graphene-based laminate not including metal oxide layer−sheet resistance value of graphene-based laminate including metal oxide layer)/resistance value of graphene-based laminate not including metal oxide layer]×100} [Equation 1]

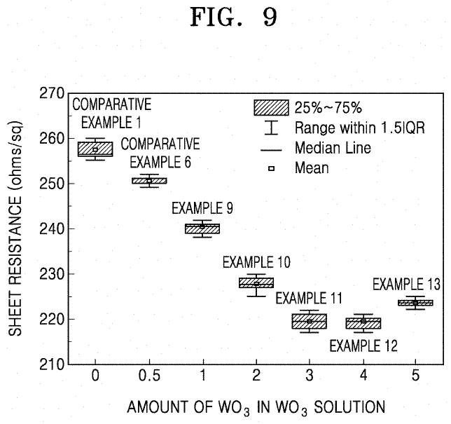

Also, sheet resistance values of the graphene-based laminates according to Examples 9 to 13 and Comparative Examples 1 and 6 were measured. The results are shown in FIG. 9.

A method of measuring sheet resistance values and a sheet resistance meter were as described above, except that the graphene-based laminates according to Examples 1 and 6 to 8 and Comparative Examples 1 and 3 to 5 were used as samples.

Referring to FIG. 9, the graphene-based laminates according to Examples 10 to 13 showed sheet resistance reduction ratios of 10% or greater than the graphene-based laminate (not including the metal oxide layer) according to Comparative Example 1. In comparison, the graphene-based laminate according to Comparative Example 6 showed a sheet resistance reduction of 3.1% or less than the graphene-based laminate (not including the metal oxide layer) according to Comparative Example 1. The sheet resistance reduction ratio was obtained by Equation 1 above.

According to an embodiment, since the graphene-based laminate and the transparent electrode including the same includes a metal oxide layer, which includes a metal oxide having a greater work function than graphene in an amount of 1 μg to 1 mg per unit area of 1 cm² of the graphene layer, the sheet resistance value may be decreased and the sheet resistance reduction ratio may efficiently be increased. In addition, according to the method of preparing the graphene-based laminate, mass production is possible regardless of sizes of samples, wetting properties of solutions are improved, and economical efficiency may be improved.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the inventive concept as defined by the following claims.

What is claimed is:

1. A graphene-based laminate comprising:
a substrate;
a graphene layer comprising graphene, and disposed on at least one surface of the substrate; and
a metal oxide layer disposed on at least one surface of the graphene layer,
wherein the metal oxide layer comprises a metal oxide having a greater work function than that of the graphene, and
wherein the metal oxide layer comprises the metal oxide in an amount of 1 μg to 1 mg per unit area of 1 cm² of the graphene layer.

2. The graphene-based laminate of claim 1, wherein a thickness of the metal oxide layer is from 1 nm to 200 nm.

3. The graphene-based laminate of claim 1, wherein the metal oxide layer occupies an area of 3% to 100% of a total area of the graphene layer.

4. The graphene-based laminate of claim 1, wherein the metal oxide comprises MoO₃, V₂O₅, CrO₃, NiO, WO₃, or a combination thereof.

5. The graphene-based laminate of claim 1, wherein the graphene layer is a single layer.

6. The graphene-based laminate of claim 1, wherein the substrate comprises polyethylene terephthalate, polycarbonate, polyimide, polyethylene naphthalate, or a glass substrate.

7. The graphene-based laminate of claim 1, wherein the graphene-based laminate has a sheet resistance reduction ratio of 10% or greater, and
wherein the sheet resistance reduction ratio is obtained using an equation below:
Sheet resistance reduction ratio (%)=Absolute value of {[(sheet resistance value of graphene-based laminate not including metal oxide layer−sheet resistance value of graphene-based laminate including metal oxide layer)/sheet resistance value of graphene-based laminate not including metal oxide layer]×100}

8. The graphene-based laminate of claim 1, wherein the graphene-based laminate further comprises a surface coating layer on the metal oxide layer.

9. A method of preparing a graphene-based laminate, the method comprising:
preparing a metal oxide solution by adding a metal oxide to a mixture of an alcohol solvent and an oxidant and stirring the mixture; and
coating the metal oxide solution on at least one surface of a graphene layer comprising graphene to form a metal oxide layer thereon, thereby obtaining the graphene-based laminate,
wherein the metal oxide layer comprises the metal oxide having a greater work function than that of the graphene, and
wherein the metal oxide layer comprises the metal oxide in an amount of 1 μg to 1 mg per unit area of 1 cm² of the graphene layer.

10. The method of claim 9, wherein a base is further added to the metal oxide solution.

11. The method of claim 9, wherein the metal oxide comprises MoO₃, V₂O₅, CrO₃, NiO, WO₃, or a combination thereof.

12. The method of claim 9, wherein the alcohol solvent comprises methanol, ethanol, propanol, butanol, isopropanol, or a mixture thereof.

13. The method of claim 9, wherein an amount of the metal oxide is from 1% by weight to 5% by weight based on the metal oxide solution.

14. The method of claim 9, wherein the oxidant comprises H₂O₂.

15. The method of claim 9, wherein a volume ratio of the metal oxide solution to the oxidant is from 1:1 to 9:1.

16. The method of claim 9, wherein a contact angle of the metal oxide solution with a surface of the graphene layer formed on the at least one surface of the substrate is 20° or less.

17. The method of claim 9, wherein the stirring is performed at a temperature of from room temperature to 100° C. for 1 hour to 24 hours.

18. The method of claim 9, wherein the coating is performed by spin coating.

19. A transparent electrode comprising the graphene-based laminate according to claim 1.

20. An electronic device comprising the transparent electrode according to claim 19.
